(19) United States
(12) Patent Application Publication
(10) Pub. No.: US 2009/0136664 A1
(43) Pub. Date: May 28, 2009

(54) Method for forming aluminide diffusion coatings

(75) Inventor: Michael J. Minor, Arlington, TX (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: United Technologies Corporation, Hartford, CT (US)

(21) Appl. No.: 11/888,691

(22) Filed: Aug. 2, 2007

(51) Int. Cl. C23C 16/06

(52) U.S. Cl. 427/252

(57) ABSTRACT

A method for forming an aluminide coating comprising diffusion coating a substrate with the use of an aluminum-based compound and a halide activator, each having a sulfur concentration of less than about 20 parts-per-million by weight.

### CROSS-REFERENCE TO RELATED APPLICATION(S)

Reference is hereby made to co-pending patent application Ser. No. ______ filed on even date (attorney docket U73.12-0175/PA-0000629-US), and entitled “Method for Forming Platinum Aluminide Diffusion Coatings”; and to co-pending patent application Ser. No. ______ filed on even date (attorney docket U73.12-0177/PA-0000627-US), and entitled “Method for Forming Active-Element Aluminide Diffusion Coatings”.

### BACKGROUND

The present invention relates to methods for coating metal components, such as aerospace components. In particular, the present invention relates to methods for forming aluminide diffusion coatings that provide corrosion and oxidation resistance.

A gas turbine engine typically consists of an inlet, a compressor, a combustor, a turbine, and an exhaust duct. The compressor draws in ambient air and increases its temperature and pressure. Fuel is added to the compressed air in the combustor, where it is burned to raise gas temperature, thereby imparting energy to the gas stream. To increase gas turbine engine efficiency, it is desirable to increase the temperature of the gas entering the turbine. This requires the first stage turbine vanes and rotor blades to be able to withstand the thermal and oxidation conditions of the high temperature combustion gas during the course of operation.

To protect the first stage turbine vanes and rotor blades from the extreme conditions, such components typically include coatings (e.g., aluminide coatings) that provide oxidation and corrosion resistance. While current aluminide coatings provide suitable levels of protection, impurities in the coatings may reduce the attainable levels of oxidation resistance. For example, sulfur impurities in aluminide coatings are known to reduce the oxidation resistances of the given coatings. As such, there is a need for a method for forming aluminide coatings that contain low concentrations of sulfur.

### SUMMARY

The present invention relates to a method for forming an aluminide coating on a substrate. The method includes diffusion coating the substrate with the use of an aluminum-based compound and a halide activator, where the aluminum-based compound and the halide activator each have a low concentration of sulfur, or are free of sulfur.

### BRIEF DESCRIPTION OF THE DRAWINGS

FIG. 1 is a sectional view of a metal component containing an aluminide diffusion coating disposed on a substrate.

FIG. 2 is a flow diagram of a method for forming the aluminide diffusion coating disposed on the substrate.

### DETAILED DESCRIPTION

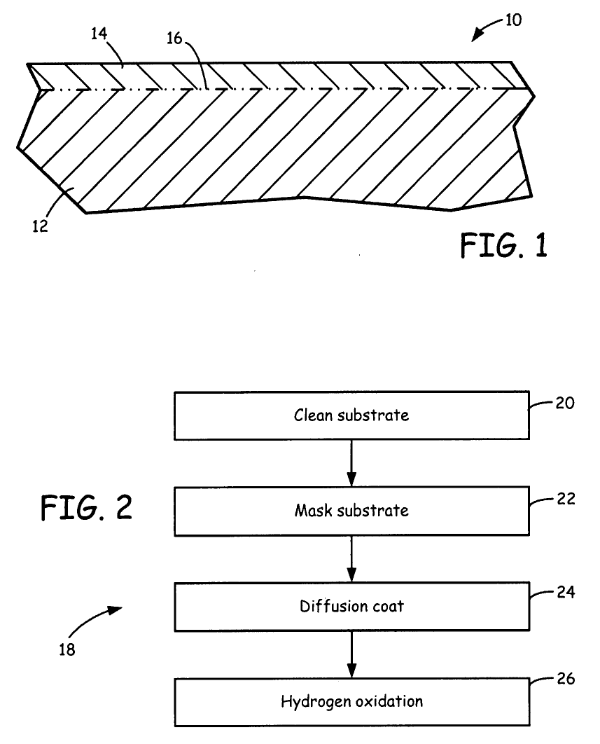

FIG. 1 is a sectional view of metal component 10, which includes substrate 12 and coating 14. Metal component 10 may be any type of component capable of containing coating 14, such as turbine engine components. Substrate 12 is a metal substrate of metal component 10, and includes surface 16. Examples of suitable materials for substrate 12 include nickel, nickel-based alloys and superalloys, cobalt, cobalt-based alloys and superalloys, and combinations thereof; and may also include one or more additional materials such as carbon, titanium, chromium, niobium, hafnium, tantalum, molybdenum, tungsten, aluminum, and iron. Surface 16 is shown with a phantom line, and illustrates the original surface of substrate 12 before coating 14 is formed.

Coating 14 is an aluminide diffusion coating interdiffused with substrate 12 at surface 16, pursuant to the present invention. Due to the interdiffusion between substrate 12 and coating 14, the materials of substrate 12 and coating 14 form one or more alloy gradients at surface 16, thereby effectively eliminating an actual surface between substrate 12 and coating 14. For example, a substantial compositional portion of coating 14 may include the materials from substrate 12 (e.g., nickel), in addition to aluminum. As discussed below, coating 14 is also substantially free of sulfur, thereby enhancing the oxidation resistance of coating 14.

FIG. 2 is a flow diagram of method 18 for forming coating 14 on substrate 12 at surface 16. Method 18 includes steps 20-26, and initially involves cleaning surface 16 of substrate 12 (step 20). Because coating 14 is desirably substantially free of sulfur, surface 16 is desirably cleaned to remove any potential impurities (e.g., sulfur) located on surface 16. Examples of suitable cleaning techniques for step 20 include fluoride-ion treatments with hydrogen fluoride gas.

One or more portions of surface 16 may then be masked to prevent the formation of coating 14 over the masked portions of surface 16 (step 22). The masking process may be performed in a variety of manners, such as with condensation-curable maskants. In one embodiment, one or more portions of substrate 12 are masked with a composition disclosed in U.S. patent application Ser. No. 11/642,424, which is commonly assigned, and entitled “Photocurable Maskant Composition and Method of Use”.

Substrate 12 is then subjected to a diffusion coating process, which desirably involves a pack cementation process (step 24). In one embodiment, the diffusion coating process involves placing substrate 12 in a container (e.g., a retort) containing a powder mixture. The powder mixture includes an aluminum-based compound and a halide activator, where the aluminum-based compound and the halide activator each have a low concentration of sulfur, or more preferably, are free of sulfur. Examples of suitable concentrations of sulfur in each of the aluminum-based compound and the halide activator include less than about 20 ppm by weight, with particularly suitable concentrations of sulfur including less than about 10 ppm by weight, and with even more particularly suitable concentrations of sulfur including less than about 5 ppm by weight. The low concentrations or lack of sulfur in the aluminum-based compound and the halide activator allow the resulting coating 14 to be substantially free of sulfur, thereby enhancing the oxidation resistance of coating 14.

The aluminum-based compound is a material that includes aluminum, and may be an aluminum-intermetallic compound. Examples of suitable aluminum-intermetallic compound for use in the diffusion coating process include chromium-aluminum (CrAl) alloys, cobalt-aluminum (CoAl) alloys, chromium-cobalt-aluminum (CrCoAl) alloys, and combinations thereof. Examples of suitable concentrations of the aluminum-based compound in the powder mixture range from about 1% by weight to about 40% by weight.

The halide activator is a compound capable of reacting with the aluminum-based compound during the diffusion coating process. Examples of suitable halide activators for use in the diffusion coating process include aluminum fluoride (AlF₃), ammonium fluoride (NH₄F), ammonium chloride (NH₄Cl), and combinations thereof. Examples of suitable concentrations of the halide activator in the powder mixture range from about 1% by weight to about 50% by weight.

The powder mixture may also include inert materials, such as aluminum oxide. The container may also include one or more gases (e.g., H₂ and argon) to obtain a desired pressure and reaction concentration during the diffusion coating process. The one or more gases are desirably clean gases (i.e., low concentrations of impurities) to reduce the risk of contaminating coating 14 during formation. In one embodiment, the one or more gases have a low combined concentration of sulfur, or more preferably, are free of sulfur. Examples of suitable concentrations of sulfur in the one or more gases include the concentrations discussed above for the aluminum-based compound and the halide activator. The use of clean gases, such as clean hydrogen, further cleans coating 14 during the diffusion coating process, thereby further reducing the concentration of sulfur in coating 14.

After substrate 12 is placed in the container and packed in a bed of the powder mixture, the container is sealed to prevent the reactants from escaping the container during the diffusion coating process. The container is then heated (e.g., in a furnace), which heats substrate 12, the aluminum-based compounds, the halide activators, and any additional materials in the container. The increased temperature initiates a reaction between the aluminum-based compounds and the halide activators to form gaseous aluminum-halide compounds. Suitable temperatures for initiating the reaction include temperatures ranging from about 650° C. (about 1200° F.) to about 1060° C. (about 2000° F.). The gaseous aluminum-halide compounds decompose at surface 16 of substrate 12, thereby depositing aluminum on surface 16 to form coating 14. The deposition of the aluminum correspondingly releases the halide activator to form additional gaseous aluminum-halide compounds while the aluminum-based compounds are still available.

Due to the elevated temperature, deposited aluminum is in a molten or partially molten state. This allows the aluminum to dissolve the material of substrate 12 at surface 16, thereby causing the material of substrate 12 and at least a portion of the aluminum to interdiffuse. The diffusion coating process is continued until a desired thickness of coating 14 is formed on substrate 12. Suitable thicknesses for providing oxidation resistance to substrate 12 range from about 25 micrometers to about 125 micrometers, with particularly suitable thicknesses ranging from about 25 micrometers to about 75 micrometers. The thicknesses of coating 14 are measured from the location of surface 16 prior to the diffusion coating process. The diffusion coating process of step 24 may be discontinued by limiting the amount of aluminum-based compounds that are available to react with the halide activators, by reducing the temperature below the reaction-initiation temperature, or by a combination thereof. The resulting coating 14 is interdiffused into substrate 12 at surface 16, thereby allowing coating 14 to protect surface 16 and substrate 12 from corrosion and oxidation during use.

The interdiffusion causes a substantial portion of coating 14 to include the material of substrate 12, in addition to aluminum. However, because the aluminum-based compounds and the halide activators contained low concentrations of sulfur (or were free of sulfur), coating 14 has a reduced concentration of sulfur, thereby enhancing the oxidation resistance of coating 14. This allows metal component 10 to exhibit greater resistance against oxidization-causing conditions, such as those that occur during the course of operating gas turbine engines.

To further enhance the oxidation resistance of coating 14, metal component 10 may subsequently undergo one or more hydrogen oxidation cycles to grow an oxide scale on coating 14 (step 26). Each hydrogen oxidation cycle involves heating metal component 10 in a dry hydrogen/oxygen atmosphere for a duration that is suitable for growing the oxide scale. Examples of suitable durations for each hydrogen oxidation cycle ranges from about 1 hour to about 5 hours. Examples of suitable temperatures for the hydrogen oxidation cycles range from about 900° C. to about 1000° C. The hydrogen used in the hydrogen oxidation cycles is beneficial for further cleaning coating 14, thereby further removing any potential impurities, and allows a substantially pure oxide scale to be grown.

After coating 14 is formed, metal component 10 may then undergo additional process steps. For example, a thermal-barrier coating may be deposited onto coating 14 to protect coating 14 and substrate 12 from extreme temperatures. Suitable thermal-barrier coatings include ceramic-based layers formed on coating 14 with standard deposition techniques (e.g., physical vapor deposition and plasma spray techniques). The composition of coating 14 (e.g., NiAl) is particularly suitable for functioning as a bonding surface for the thermal-barrier coating, particularly with the formation of an oxide scale. Thus, in addition to providing oxidation and corrosion protection, coating 14 formed pursuant to the present invention is also suitable for functioning as a bond layer for a thermal-barrier coating.

Although the present invention has been described with reference to preferred embodiments, workers skilled in the art will recognize that changes may be made in form and detail without departing from the spirit and scope of the invention.

1. A method for forming an aluminide coating on a substrate, the method comprising:
exposing the substrate to an aluminum-based compound and a halide activator, the aluminum-based compound and the halide activator each having a sulfur concentration of less than about 20 parts-per-million by weight; and
performing a diffusion coating process on the substrate with the aluminum-based compound and the halide activator.

2. The method of claim 1, wherein the sulfur concentration of at least one of the aluminum-based compound and the halide activator is less than about 10 parts-per-million by weight sulfur.

3. The method of claim 2, wherein the sulfur concentration of the at least one of the aluminum-based compound and the halide activator is less than about 5 parts-per-million by weight sulfur.

4. The method of claim 1, wherein performing the diffusion coating process comprises:
heating the aluminum-based compound and the halide activator to form an aluminum-halide compound; and
depositing aluminum from the aluminum-halide compound onto the substrate.

5. The method of claim 1, wherein the aluminum-based compound is selected from the group consisting of chromium-aluminum (CrAl) alloys, cobalt-aluminum (CoAl) alloys, chromium-cobalt-aluminum (CrCoAl) alloys, and combinations thereof.

6. The method of claim 1, wherein the halide activator is selected from the group consisting of aluminum fluoride, ammonium fluoride, ammonium chloride, and combinations thereof.

7. The method of claim 1, wherein the substrate comprises a material selected from the group consisting of nickel-based alloys, nickel-based superalloys, cobalt-based alloys, cobalt-based superalloys, and combinations thereof.

8. The method of claim 1, further comprising exposing the deposited aluminide coating to at least one hydrogen oxidation cycle.

9. The method of claim 1, further comprising exposing the substrate to hydrogen gas having a sulfur concentration of less than about 20 parts-per-million by weight.

10. A method for forming an aluminide coating on a substrate, the method comprising:
introducing an aluminum-based compound and a halide activator into a container, the aluminum-based compound and the halide activator each having a sulfur concentration of less than about 20 parts-per-million by weight;
placing the substrate in the container;
forming an aluminum-halide compound from the aluminum-based compound and the halide activator; and
depositing aluminum from the aluminum-halide compound onto the substrate.

11. The method of claim 10, wherein the sulfur concentration of at least one of the aluminum-based compound and the halide activator is less than about 10 parts-per-million by weight sulfur.

12. The method of claim 11, wherein the sulfur concentration of the at least one of the aluminum-based compound and the halide activator is less than about 5 parts-per-million by weight sulfur.

13. The method of claim 10, further comprising exposing the substrate to at least one hydrogen oxidation cycle.

14. The method of claim 10, further comprising introducing hydrogen gas to the container, the hydrogen gas having a sulfur concentration of less than about 20 parts-per-million by weight.

15. A method for forming an aluminide coating on a substrate, the method comprising:
placing the substrate in a container;
reacting an aluminum-based compound and a halide activator in the container to form an aluminum-halide compound in the container, wherein the aluminum-based compound and the halide activator each have a sulfur concentration of less than about 20 parts-per-million by weight; and
interdiffusing at least a portion of the aluminum from the aluminum-halide compound into the substrate.

16. The method of claim 15, wherein the sulfur concentration of at least one of the aluminum-based compound and the halide activator is less than about 10 parts-per-million by weight sulfur.

17. The method of claim 16, wherein the sulfur concentration of the at least one of the aluminum-based compound and the halide activator is less than about 5 parts-per-million by weight sulfur.

18. The method of claim 15, wherein reacting the aluminum-based compound and the halide activator comprises heating the container to a temperature ranging from about 650° C. to about 1060° C.

19. The method of claim 15, wherein the substrate comprises a material selected from the group consisting of nickel-based alloys, nickel-based superalloys, cobalt-based alloys, cobalt-based superalloys, and combinations thereof.

20. The method of claim 15, further comprising exposing the substrate to at least one hydrogen oxidation cycle.
